(19) United States
(12) Patent Application Publication
(10) Pub. No.: US 2006/0138403 A1
(43) Pub. Date: Jun. 29, 2006

(54) Organic electronic devices including pixels

(76) Inventor: Gang Yu, Santa Barbara, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/025,755

(22) Filed: Dec. 29, 2004

(51) Int. Cl. F16L 33/00; H01L 29/08

(52) U.S. Cl. 257/40; 285/249

(57) ABSTRACT

An organic electronic device includes a pixel. The pixel includes a first transistor and a capacitive electronic component. In one embodiment, the first transistor is an under-gated TFT, and a first portion of a first conductive member is a gate electrode of the first transistor. A second portion of the first conductive member is a first electrode of the capacitive electronic component. In another embodiment, from a plan view, the first transistor has a length and a width. The length of the first transistor is larger than the width of the first transistor. The capacitive electronic component has a length and a width. The length of the capacitive electronic component is larger than the width of the capacitive electronic component. The first transistor and the capacitive electronic component are substantially contiguous to each other.

### BACKGROUND OF THE INVENTION

1. Field of the Invention

This invention relates in general to electronic devices, and more particularly, to organic electronic devices including pixels.

2. Description of the Related Art

Electronic devices, including organic electronic devices, continue to be more extensively used in everyday life. Examples of organic electronic devices include Organic Light-Emitting Diodes (“OLEDs”). Active Matrix OLED (“AMOLED”) displays include pixels each having a pixel circuits. A conventional pixel has a rectangular shape with a pair of shorter opposing sides along the width of the pixel, and a pair of longer opposing sides along the length of the pixel. A typical layout for a pixel has a pixel driving circuit, such that, from a plan view, an area occupied by the pixel driving circuit lies between the longer sides and extends from one of the shorter sides partially toward the other shorter side. That same layout has an area occupied by the OLED that lies between the longer sides and extends from the other shorter side towards the pixel driving circuit. The aperture-ratio using this layout is typically no greater than 35% for a bottom emission electronic device.

### SUMMARY OF THE INVENTION

An organic electronic device includes a pixel, wherein the pixel includes a first transistor and a capacitive electronic component. In one embodiment, the first transistor is an under-gated TFT, and a first portion of a first conductive member is a gate electrode of the first transistor. A second portion of the first conductive member is a first electrode of the capacitive electronic component.

In one embodiment, an organic electronic device includes a pixel. The pixel includes a first transistor. From a plan view, the first transistor has a length and a width, wherein the length of the first transistor is larger than the width of the first transistor. The pixel also includes a capacitive electronic component. From a plan view, the capacitive electronic component has a length and a width, wherein the length of the capacitive electronic component is larger than the width of the capacitive electronic component. From a plan view, the first transistor and the capacitive electronic component are substantially contiguous to each other along a line that is substantially parallel to the lengths of the first transistor and the capacitive electronic component.

The foregoing general description and the following detailed description are exemplary and explanatory only and are not restrictive of the invention, as defined in the appended claims.

### BRIEF DESCRIPTION OF THE DRAWINGS

The invention is illustrated by way of example and not limitation in the accompanying figures.

FIG. 1 includes a circuit diagram including pixel circuits within an electronic device.

FIGS. 2 and 3 include illustrations of a plan view and a cross-sectional view, respectively, of a portion of an array after forming a first set of conductive members over a substrate.

FIG. 4 includes an illustration of a cross-sectional view of the portion of an array of FIG. 3 after forming a gate dielectric layer, a first semiconductor layer, and a second semiconductor layer.

FIGS. 5 and 6 include illustrations of a plan view and a cross-sectional view, respectively, of the portion of an array of FIGS. 2 and 4 after patterning the first and second semiconductor layers.

FIGS. 7 and 8 include illustrations of a plan view and a cross-sectional view, respectively, of the portion of an array of FIGS. 5 and 6 after forming a second set of conductive members over portions of the first and second semiconductor layers.

FIG. 9 includes an illustration of a cross-sectional view of the portion of an array of FIG. 8 after etching a portion of the second semiconductor layer to define a channel region within the first semiconductor layer.

FIGS. 10 and 11 include illustrations of a plan view and a cross-sectional view, respectively, of the portion of an array of FIGS. 7 and 9 after forming a third set of conductive members over portions of the substrate.

FIGS. 12 and 13 include illustrations of a plan view and a cross-sectional view, respectively, of the portion of an array of FIGS. 10 and 11 after forming a substrate structure over at least portions of the pixel driving circuits.

FIG. 14 includes an illustration of a cross-sectional view of the portion of an array of FIG. 13 after forming a substantially completed electronic device.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

An organic electronic device includes a pixel, wherein the pixel includes a first transistor and a capacitive electronic component. In one embodiment, the first transistor is an under-gated TFT, and a first portion of a first conductive member is a gate electrode of the first transistor. A second portion of the first conductive member is a first electrode of the capacitive electronic component.

In another embodiment, a first portion of a second conductive member is a contact structure for a source/drain region of the first transistor. A second portion of the second conductive member is a second electrode of the capacitive electronic component. In a specific embodiment, a first portion of a first layer is at least part of a gate dielectric layer for the first transistor. A second portion of the first layer is at least part of a capacitor dielectric layer for the capacitive electronic component. In another specific embodiment, the first transistor includes a channel region that includes a portion of a first semiconductor layer. The first transistor also includes source/drain regions that are spaced-apart portions of a second semiconductor layer overlying the first semiconductor layer. The second semiconductor layer contacts and overlies the channel region and source/drain regions of the first transistor. In a more specific embodiment, from a cross-sectional view, at least a portion of the source/drain regions lies between the first and second conductive members. In still a more specific embodiment, the pixel further includes a select transistor that is an under-gated TFT. In yet another specific embodiment, the first semiconductor layer was formed as amorphous silicon (a-Si), low-temperature polysilicon (LTPS), continuous grain silicon (CGS), or any combination thereof.

In still another embodiment, the organic electronic device is a bottom emission electronic device, and the pixel has an aperture ratio of at least 40%. In yet another embodiment, the organic electronic device further includes a select transistor. The select transistor includes a channel region, the channel region of the select transistor, the first transistor, or both has a physical channel length, and the physical channel length is no more than 2 times greater than a minimum dimension of design rules for the organic electronic device. In a specific embodiment, the physical channel length is no more than 1.2 times greater than the minimum dimension of the design rules for the organic electronic device.

In one embodiment, an organic electronic device includes a pixel. The pixel includes a first transistor. From a plan view, the first transistor has a length and a width, wherein the length of the first transistor is larger than the width of the first transistor. The pixel also includes a capacitive electronic component. From a plan view, the capacitive electronic component has a length and a width, wherein the length of the capacitive electronic component is larger than the width of the capacitive electronic component. From a plan view, the first transistor and the capacitive electronic component are substantially contiguous to each other along a line that is substantially parallel to the lengths of the first transistor and the capacitive electronic component.

In another embodiment, the pixel includes a single conductive member that is a gate electrode for the first transistor and a first electrode for the capacitive electronic component. In a specific embodiment, the pixel includes a first conductive member and a second conductive member. A first portion of the first conductive member is a first source/drain region of the first transistor, and a first portion of the second conductive member is a second electrode of the capacitive electronic component. In a more specific embodiment, the pixel includes a dielectric layer. A first portion of a dielectric layer is at least part of a gate dielectric layer for the first transistor, and a second portion of the dielectric layer is at least part of a capacitor dielectric layer for the capacitive electronic component. In another more specific embodiment, the first transistor includes a channel region that includes a portion of a first semiconductor layer. The first source/drain region and a second source/drain region are spaced-apart portions of a second semiconductor layer overlying the first semiconductor layer. The second semiconductor layer contacts and overlies the first semiconductor layer. In still another more specific embodiment, the first semiconductor layer was formed as amorphous silicon (a-Si), low-temperature polysilicon (LTPS), continuous grain silicon (CGS), or any combination thereof.

In still another more specific embodiment, the pixel further includes a select transistor that is an under-gated TFT. In yet a further specific embodiment, the select transistor, the first transistor, or both include a channel region. The channel region of the select transistor, the first transistor, or both has a physical channel length. The physical channel length is no more than 2 times greater than a minimum dimension of design rules for the organic electronic device. In yet another further specific embodiment, the physical channel length is no more than 1.2 times greater than the minimum dimension of the design rules for the organic electronic device.

In yet another specific embodiment, the organic electronic device is a bottom emission electronic device. The pixel has an aperture ratio of at least 40%.

The detailed description first addresses Definitions and Clarification of Terms followed by Circuit Diagram, Pixel Layout and Electronic Device Fabrication, Other Embodiments, and finally, Advantages.

1. Definitions and Clarification of Terms

Before addressing details of embodiments described below, some terms are defined or clarified. The term “amorphous silicon” (“a-Si”) is intended to mean one or more layers of silicon having no discernible crystalline structure.

The term “aperture ratio” is intended to mean a ratio of the area of the pixel available for emitting or responding to radiation to the total area of a pixel. The aperture ratio is typically expressed as a percentage.

The terms “array,” “peripheral circuitry,” and “remote circuitry” are intended to mean different areas or components of an electronic device. For example, an array may include pixels, cells, or other structures within an orderly arrangement (usually designated by columns and rows). The pixels, cells, or other structures within the array may be controlled locally by peripheral circuitry, which may lie on the same substrate as the array but outside the array itself. Remote circuitry typically lies away from the peripheral circuitry and can send signals to or receive signals from the array (typically via the peripheral circuitry). The remote circuitry may also perform functions unrelated to the array. The remote circuitry may or may not reside on the substrate having the array.

The term “black layer” is intended to mean a layer that transmits no more than approximately 10% of radiation at a targeted wavelength or spectrum.

The term “bottom emission,” when referring to a display or other electronic device, is intended to mean that (a) radiation from a radiation-emitting component is designed to be emitted through a substrate over which the radiation-emitting component is formed, (b) radiation to a radiation-responsive component is designed to be received through the substrate over which the radiation-responsive component is formed, or (c) any combination thereof.

The term “capacitive electronic component” is intended to mean an electronic component configured to act as a capacitor when illustrated in a circuit diagram. An example of a capacitive electronic component includes a capacitor or transistor structure.

The term “capacitor dielectric layer” is intended to mean one or more dielectric layers within a capacitive electronic component lying between the electrodes of the capacitive electronic component.

The term “channel region” is intended to mean a region lying between source/drain regions of a field-effect transistor, whose biasing, via a gate electrode of the field-effect transistor, affects the flow of carriers, or lack thereof, between the source/drain regions.

The term “circuit” is intended to mean a collection of electronic components that collectively, when properly connected and supplied with the proper potential(s), performs a function. A TFT driver circuit for an organic electronic component is an example of a circuit.

The term “connected,” with respect to electronic components, circuits, or portions thereof, is intended to mean that two or more electronic components, circuits, or any combination of at least one electronic component and at least one circuit do not have any intervening electronic component lying between them. Parasitic resistance, parasitic capacitance, or both are not considered electronic components for the purposes of this definition. In one embodiment, electronic components are connected when they are electrically shorted to one another and lie at substantially the same voltage. Note that electronic components can be connected together using fiber optic lines to allow optical signals to be transmitted between such electronic components.

The term “contiguous” is intended to mean touching along a boundary. Two objects that are contiguous may or may not have a visibly discernable border.

The term “continuous grain silicon” (“CGS”) is intended to mean a type of polysilicon in which individual crystals are oriented in a direction parallel to the channel length of a field-effect transistor. The oriented crystals reduce the frequency with which a charge encounters a grain boundary, resulting in an overall higher mobility of the channel region compared to a randomly oriented polysilicon channel.

The term “coterminous” is intended to mean having the same or coincident boundaries.

The term “coupled” is intended to mean a connection, linking, or association of two or more electronic components, circuits, systems, or any combination of at least two of: (1) at least one electronic component, (2) at least one circuit, or (3) at least one system in such a way that a signal (e.g., current, voltage, or optical signal) may be transferred from one to another. A non-limiting example of “coupled” can include a direct connection between electronic component(s), circuit(s) or electronic component(s) or circuit(s) with switch(es) (e.g., transistor(s)) connected between them.

The term “data line” is intended to mean a signal line having a primary function of transmitting one or more signals that comprise information.

The term “design rules” is intended to mean a set of rules or guidelines to which a design of an electronic component, electronic device, or a combination thereof is to comply. A set of design rules is typically referred to by the smallest dimension of a feature that the set of design rules can support.

The term “driving transistor” is intended to mean a transistor, by itself or in conjunction with one or more other electronic components, controls the signal intensity (e.g., amount of current) flowing to another electronic component.

The term “electronic component” is intended to mean a lowest level unit of a circuit that performs an electrical function. An electronic component may include a transistor, a diode, a resistor, a capacitor, an inductor, or the like. An electronic component does not include parasitic resistance (e.g., resistance of a wire) or parasitic capacitance (e.g., capacitive coupling between two conductors connected to different electronic components where a capacitor between the conductors is unintended or incidental).

The term “field-effect transistor” is intended to mean a transistor, whose current-carrying characteristics are affected by a voltage on a gate electrode. Field-effect transistors include junction field-effect transistors (JFETs) and metal-insulator-semiconductor field-effect transistors (MISFETs), including metal-oxide-semiconductor field-effect transistors (MOSFETs), metal-nitride-oxide-semiconductor (MNOS) field-effect transistors, or combinations thereof. A field-effect transistor can be n-channel (n-type carriers flowing within the channel region) or p-channel (p-type carriers flowing within the channel region). A field-effect transistor may be an enhancement-mode transistor (channel region having a different conductivity type compared to the source/drain regions of the same field-effect transistor) or depletion-mode transistor (channel and source/drain regions of the same field-effect transistor have the same conductivity type).

The term “gate dielectric layer” is intended to mean one or more dielectric layers lying between a channel region of the field-effect transistor and a gate electrode of the same field-effect transistor.

The term “low-temperature polysilicon” (“LTPS”) is intended to mean one or more layers of polysilicon deposited or processed at a temperature no greater than 550° C. One example of a process for forming LTPS is Sequential Lateral Solidification (“SL 362S”), in which a modified excimer laser crystallization (“ELC”) process is used to form oriented grains of larger sizes, resulting in higher mobilities for charge carriers, when compared to conventional ELC techniques for forming LTPS.

The term “minimum dimension,” when referring to design rules, is intended to mean the smallest dimension of a feature allowed by a set of design rules. For example, the minimum dimension for 4-micron design rules is 4 microns.

The term “n⁺ doped” or “p⁺ doped,” with respect to a material, layer, or region is intended to mean such material, layer, or region includes a sufficient amount of an n-type or p-type dopant, such that such doped material, layer, or region is capable of forming an ohmic contact when a metal-containing material or layer contacts such doped material, layer, or region. In one embodiment, an n+ doped region has at least 1×10¹⁹ negatively charged carriers/cm³.

The term “organic active layer” is intended tomean one or more organic layers, wherein at least one of the organic layers, by itself or when in contact with a dissimilar material, is capable of forming a rectifying junction.

The term “organic electronic device” is intended to mean a device including one or more organic semiconductor layers or materials. An organic electronic device includes: (1) a device that converts electrical energy into radiation (e.g., a light-emitting diode, light-emitting diode display, diode laser, or lighting panel), (2) a device that detects a signal through an electronic process (e.g., a photodetector (e.g., a photoconductive cell, a photoresistor, a photoswitch, a phototransistor, a phototube), an infrared (“IR”) detector, a biosensor), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

The term “physical channel length” is intended to mean the actual distance between the source/drain regions of a field-effect transistor.

The term “pixel” is intended to mean a portion of an array corresponding to one electronic component and its corresponding electronic component(s), if any, that are dedicated to that specific one electronic component. In one embodiment, a pixel has an OLED and its corresponding pixel driving circuit Note that a pixel as used in this specification can be a pixel or subpixel as those terms are used by skilled artisans outside of this specification.

The term “pixel circuit” is intended to mean a circuit within a pixel. In one embodiment, the pixel circuit may be used in a display or a sensor array.

The term “pixel driving circuit” is intended to mean a circuit within a pixel that controls signal(s) for no more than one electronic component driving by such circuit.

The term “polysilicon” is intended to mean a layer of silicon made up of randomly oriented crystals.

The term “radiation-emitting component” is intended to mean an electronic component, which when properly biased, emits radiation at a targeted wavelength or spectrum of wavelengths. The radiation may be within the visible-light spectrum or outside the visible-light spectrum (ultraviolet (“UV”) or IR). A light-emitting diode is an example of a radiation-emitting component.

The term “radiation-responsive component” is intended to mean an electronic component can respond to radiation at a targeted wavelength or spectrum of wavelengths. The radiation may be within the visible-light spectrum or outside the visible-light spectrum (UV or IR). An IR sensor and a photovoltaic cell are examples of radiation-sensing components.

The term “rectifying junction” is intended to mean a junction within semiconductor layer or a junction formed by an interface between a semiconductor layer and a dissimilar material in which charge carriers of one type flow easier in one direction through the junction compare to the opposition direction. A pn junction is an example of a rectifying junction that can be used as a diode.

The term “select line” is intended to mean a specific signal line within a set of signal lines having a primary function of transmitting one or more signals used to activate one or more electronic components, one or more circuits, or any combination thereof when the specific signal line is activated, wherein other electronic component(s), circuit(s), or any combination thereof associated with another signal line within the set of signal lines are not activated when the specific signal line is activated. The signals lines within the set of signal lines may or may not be activated as a function of time.

The term “select transistor” is intended to mean a transistor controlled by a signal on a select line.

The term “semiconductor” is intended to mean a material that is capable of including or having a rectifying junction formed therein or when such material is in contact with a dissimilar material (e.g., a metal-containing material).

The term “signal” is intended to mean a current, a voltage, an optical signal, or any combination thereof. The signal can be a voltage or current from a power supply or can represent, by itself or in combination with other signal(s), data or other information. Optical signals can be based on pulses, intensity, or a combination thereof. Signals may be substantially constant (e.g., power supply voltages) or may vary over time (e.g., one voltage for on and another voltage for off).

The term “signal line” is intended to mean a line over which one or more signals may be transmitted. The signal to be transmitted may be substantially constant or vary. Signal lines can include control lines, data lines, scan lines, select lines, power supply lines, or any combination thereof. Note that signal lines may serve one or more principal functions.

The term “source/drain region” is intended to mean a region of a field-effect transistor that injects charge carriers into a channel region or receives charge carriers from the channel region. A source/drain region can include a source region or a drain region, depending on the flow of current through the field-effect transistor. A source/drain region may act as source region when current flows in one direction through the field-effect transistor, and as a drain region when current flows in the opposite direction through the field-effect transistor.

The term “under-gated,” when referring to a field-effect transistor, is intended to mean that a gate electrode of the field-effect transistor lies between a channel region of the field-effect transistor and a substrate over which the field-effect transistor is formed.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an “inclusive or” and not to an “exclusive or.” For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Unless otherwise defined, all technical and scientific terms used herein have the same meaning as commonly understood by one of ordinary skill in the art to which this invention belongs. Although suitable methods and materials are described herein for embodiments of the invention, or methods for making or using the same, other methods and materials similar or equivalent to those described can be used without departing from the scope of the invention. All publications, patent applications, patents, and other references mentioned herein are incorporated by reference in their entirety. In case of conflict, the present specification, including definitions, will control. In addition, the materials, methods, and examples are illustrative only and not intended to be limiting.

Group numbers corresponding to columns within the periodic table of the elements use the “New Notation” convention as seen in the CRC Handbook of Chemistry and Physics, 81 st Edition (2000).

To the extent not described herein, many details regarding specific materials, processing acts, and circuits are conventional and may be found in textbooks and other sources within the organic light-emitting display, photodetector, semiconductor, and microelectronic circuit arts. Details regarding radiation-emitting elements, pixels, and pixel circuitry will be addressed before turning to details of the radiation-sensing elements and circuitry.

2. Circuit Diagram

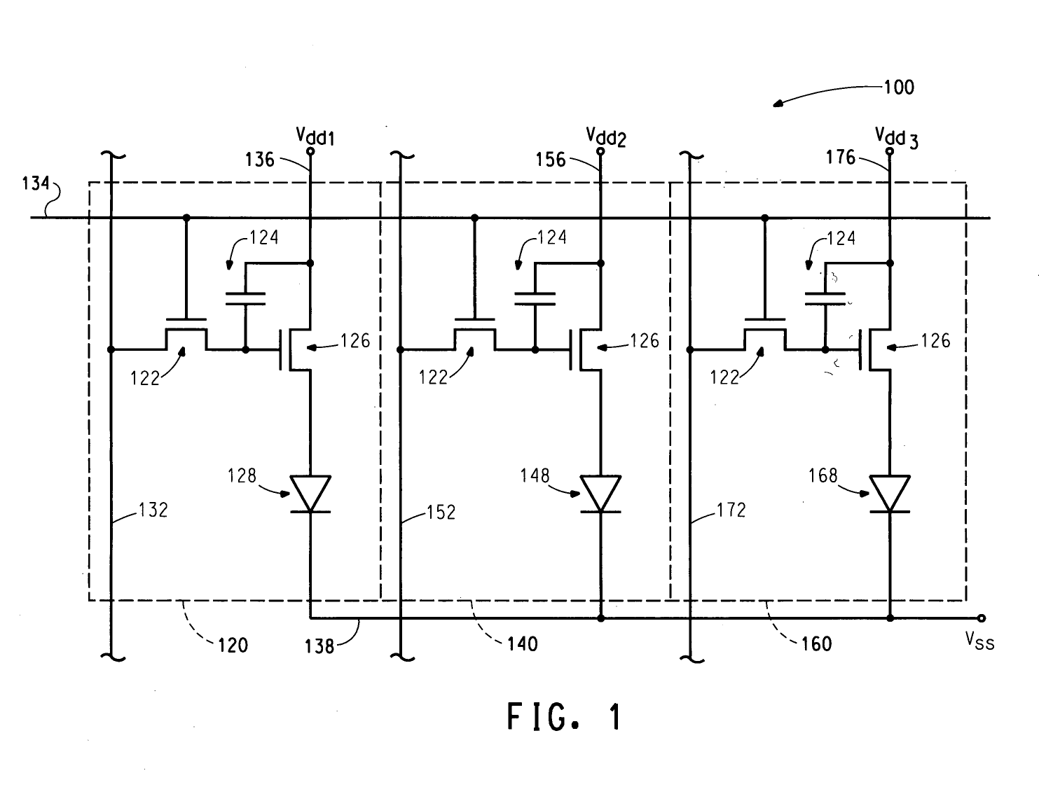

FIG. 1 includes a circuit diagram of a portion of an electronic device 100. The electronic device 100 includes a first pixel 120, a second pixel 140, and a third pixel 160. Each of the pixels 120, 140, and 160 includes a pixel circuit as illustrated in FIG. 1. Each pixel circuit includes a pixel driving circuit and an electronic component 128, 148, or 168.

The first pixel 120 includes a select transistor 122, a capacitive electronic component 124, a driving transistor 126, and an electronic component 128. The electronic component 128 can be nearly any electronic component that is driven by an electrical current. In one embodiment, the electronic component 128 is a radiation-emitting component, such as an OLED.

Within pixel 120, the pixel driving circuit includes a select transistor 122. The select transistor 122 includes a gate electrode connected to a select line (“SL”) 134, a first source/drain region connected to a data line (“DL”) 132, and a second source/drain region connected to a first electrode of a capacitive electronic component 124, and a gate electrode of a driving transistor 126. SL 134 provides a control signal for the select transistor 122, and DL 132 provides a data signal to be passed to the capacitive electronic component 124 and the gate electrode of the driving transistor 126 when the select transistor 122 is activated.

The pixel driving circuit also includes the capacitive electronic component 124. The capacitive electronic component 124 includes the first electrode and a second electrode. The first electrode of the capacitive electronic component 124 is connected to the second source/drain region of the select transistor 122 and the gate electrode of the driving transistor 126. The second electrode of the capacitive electronic component 124 is connected to a first power supply line, which in one embodiment is a V_{dd1} line 136. In an alternative embodiment (not illustrated), an optional anti-degradation unit may be connected to the capacitive electronic component 124 and at least one of the power supply lines (e.g., Vₛₛ line 138, V_{dd1} line 136, or both) connected to the pixel 120.

The pixel driving circuit further includes the driving transistor 126. The driving transistor 126 includes the first gate electrode, a first source/drain region, and a second source/drain region. The first source/drain region of the driving transistor 126 is connected to a first electrode of the electronic component 128, and the second source/drain region of the driving transistor 126 is connected to the V_{dd1} line 136.

The pixel driving circuit still further includes the electronic component 128. The electronic component 128 includes the first electrode and a second electrode that is connected to the Vₛₛ line 138. In one embodiment, the first electrode is an anode, and the second electrode is a cathode. In another embodiment, the electronic component 128 is an organic, radiation-emitting electronic component, such as an OLED. The rest of the pixel circuit, which is the pixel driving circuit in one embodiment, is well suited for providing a variable current source to drive the electronic component 128. Therefore, one or more electronic components that are current driven may be used in place of or in conjunction with the electronic component 128. Note that the one or more electronic components may or may not include a diode.

In another embodiment (not shown), the electronic component 128 and driving transistor 126 may be reversed. More specifically, (1) the first electrode (e.g., anode) of the electronic component 128 is connected to the V_{dd1} line 136, (2) the second electrode (e.g., cathode) of the electronic component 128 is connected to one of the source/drain regions of the driving transistor 126, and (3) the other source/drain region of the driving transistor 126 is connected to the Vₛₛ line 138.

The second pixel 140 is similar to the first pixel 120 except that, within the second pixel 140, a data line 152 is connected to a first source/drain region of the select transistor 122, a V_{dd2} line 156 is connected to second source/drain region of the driving transistor 126, and an electronic component 148 is connected between a first source/drain region of the driving transistor 126 and the Vₛₛ line 138. The third pixel 160 is similar to the first and second pixels 120 and 140 except that, within the third pixel 160, a data line 172 is connected to a first source/drain region of the select transistor 122, a V_{dd3} line 176 is connected to second source/drain region of the driving transistor 126, and an electronic component 168 is connected between a first source/drain region of the driving transistor 126 and the Vₛₛ line 138.

In one embodiment, the electronic components 128, 148, 168 are substantially identical to one another. In another embodiment, the electronic components 128, 148, and 168 are different from one another. For example, the electronic component 128 is a blue light emitting component, the electronic component 148 is a green light emitting component, and the electronic component 168 is a red light emitting component. The V_{dd1}, V_{dd2}, and V_{dd3} lines 136, 156, and 176 may be at the same or different voltages compared to one another. In another embodiment (not illustrated), the second electrodes of the electronic components 128, 148, 168 may be connected to different power supply lines that may operate at substantially the same or significantly different voltages. After reading this specification, skilled artisans will be able to design the electronic device 100 to meet the needs or desires for a specific application.

The select transistor 122, driving transistor 126, or any combination thereof can include a field-effect transistor. In the circuit for the pixel as illustrated in FIG. 1, all transistors are n-channel transistors. Any one or more of the n-channel transistors can be replaced by any one or more p-channel transistors. In other embodiments, other transistors (including JFETs and bipolar transistors) may be used within the select transistor 122.

3. Pixel Layout and Electronic Device Fabrication

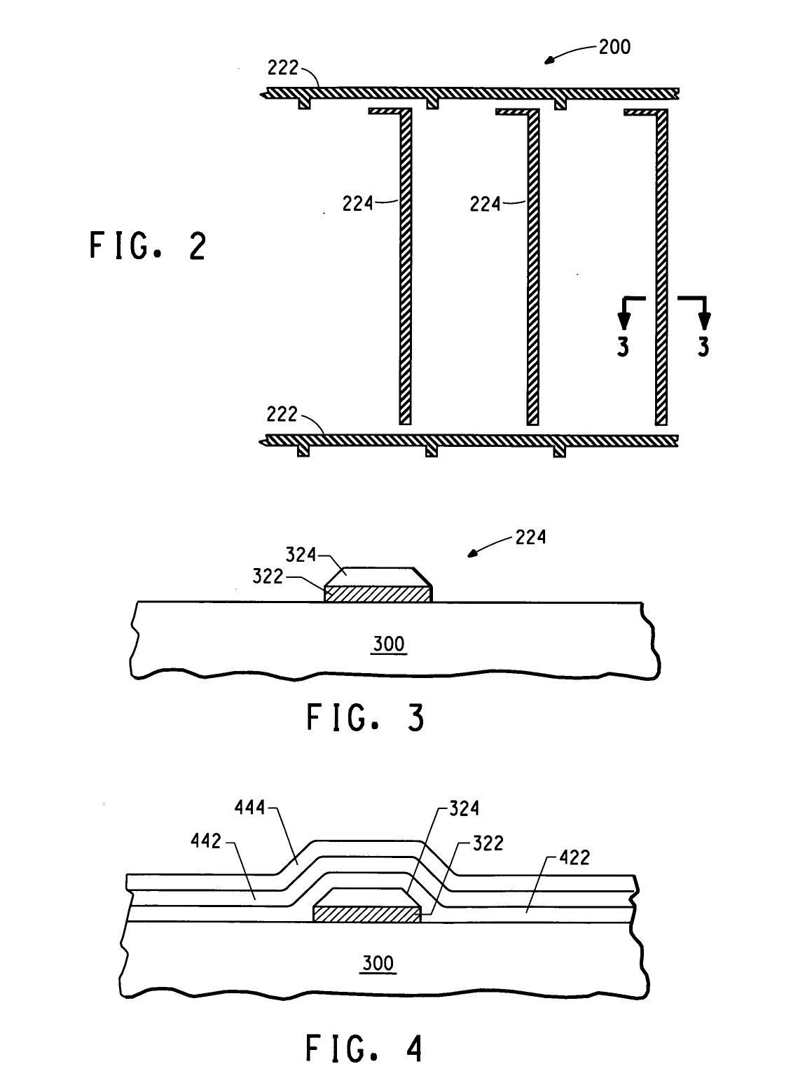

FIGS. 2 to 14 include illustrations of plan views and cross-sectional views of a portion of the electronic device during the formation of the circuits as illustrated in FIG. 1. The drawings merely illustrate a few embodiments for a layout and fabrication sequence for forming the electronic components and their interconnects within the circuits. After reading this specification, skilled artisans will appreciate that other layouts may be used in forming the circuits as illustrated in FIG. 1. For simplicity, dielectric and insulating layers are not illustrated in the plan views.

FIGS. 2 and 3 include illustrations of a plan view and a cross-sectional view, respectively, of a portion of an array 200 after forming conductive members 222 and 224. Conductive members 222 are portions of select lines 134 for two rows of pixels. The conductive member 222 that is closer to the top of FIG. 2 is the select line for the pixel illustrated in FIG. 1. The other conductive member 222, which is closer to the bottom of FIG. 2, is the select line for the pixel (not illustrated) in the row below the pixel being formed. Portions of the conductive members 222 that are subsequently covered by active regions are gate electrodes for the select transistors 122. In one embodiment, conductive members 224 are the first electrodes of the capacitive electronic components 124 and the gate electrodes for the driving transistors 126.

FIG. 3 includes an illustration of a cross-sectional view of a portion of a substrate 300 and one of the conductive members 224 as seen at sectioning line 3-3. The substrate 300 can be rigid or flexible and may contain one or more layers of an organic, inorganic, or both organic and inorganic materials. In one embodiment, the electronic device includes a bottom emission display, and the substrate 300 includes a transparent material that allows at least 70% of the radiation incident on the substrate 300 to be transmitted through it.

Each of the conductive members 222 and 224 includes a black layer 322 and a conductive layer 324 and are formed over the substrate 300. In one embodiment, the black layer 322 and the conductive layer 324 can be formed using a conventional deposition and optional patterning sequence. For example, the layers for the black layer 322 and conductive layer 324 can be deposited as patterned layers using a stencil mask. In another embodiment, the layers for the black layer 322 and conductive layer 324 may be sequentially deposited over the substrate 300, and the black layer 322 and the conductive layer 324 may be patterned using a conventional lithographic process. In still another embodiment, the black layer 322 may be formed over substantially all of the substrate 300, and the conductive layer 324 may be deposited as a patterned layer over the black layer 322. The conductive layer 324 can act as a hard mask during an etching step to remove portions of the black layer 322 that are not covered by the conductive layer 324. In another embodiment, the black layer 322 may be omitted, and the conductive layer 324 may be formed on the surface of the substrate 300. After reading the specification, skilled artisans will appreciate that many other techniques may be used in forming the black layer 322 and the conductive layer 324.

The black layer 322 allows for an improved contrast ratio of the electronic device when used in ambient light conditions. Materials and thicknesses of the black layer are more fully described in U.S. patent application Ser. No. 10/840,807 entitled “Array Comprising Organic Electronic Devices With a Black Lattice and Process For Forming the Same” by Gang Yu-et al. filed May 7, 2004. In one embodiment, the black layer 322 includes one or more layers of Cr, Ni, or both.

The conductive layer 324 may include one or more layers that include at least one element selected from Groups 4 to 6, 8 and 10 to 14 of the Periodic Table, or any combination thereof. In one embodiment, the conductive layer 324 can include Cu, Al, Ag, Au, Mo, or any combination thereof. In another embodiment, where the conductive layer 324 includes more than one layer, one of the layers can include can include Cu, Al, Ag, Au, Mo, or any combination thereof and another layer can include Mo, Cr, Ti, Ru, Ta, W, Si, or any combination thereof. Note that conductive metal oxide(s), conductive metal nitride(s) or a combination thereof may be used in place of or in conjunction with any of the elemental metals or alloys thereof. In one embodiment, the first gate electrode has a thickness in a range of approximately 0.2 to 5 microns.

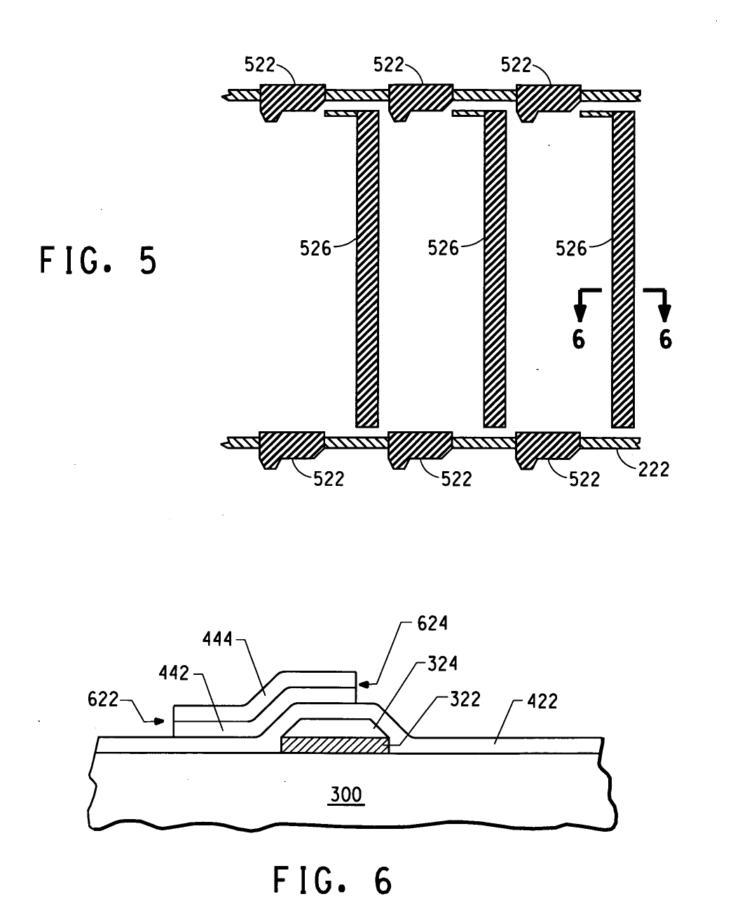

A dielectric layer 422, a first semiconductor layer 442, and a second semiconductor layer 444 are sequentially formed over the substrate 300 and the conductive layer 324 as illustrated in FIG. 4. Each of the dielectric layer 422, a first semiconductor layer 442, and the second semiconductor layer 444 can be formed using conventional deposition techniques.

The dielectric layer 422 can include one or more layers including silicon dioxide, alumina, hafnium oxide, silicon nitride, aluminum nitride, silicon oxynitride, another conventional gate dielectric material as used in the semiconductor arts, or any combination thereof. In another embodiment, thickness of the dielectric layer 422 is in a range of approximately 50 to 1000 nm.

Each of the first and second semiconductor layers 442 and 444 can include one or more materials conventionally used as semiconductors in electronic components. In one embodiment, the first semiconductor layer 442, the second semiconductor layer 444, or both are formed (e.g., deposited) as amorphous silicon (a-Si), low-temperature polysilicon (LTPS), continuous grain silicon (CGS), or any combination thereof. In another embodiment, other Group 14 elements (e.g., carbon, germanium), by themselves or in combination (with or without silicon), may be used for the first semiconductor layer 442, the second semiconductor layer 444, or both. In still other embodiments, the first and second semiconductor layers 442 and 444 include III-V (Group 13-Group 15) semiconductors (e.g., GaAs, InP, GaAIAs, etc.), II-VI (Group 2-Group 16 or Group 12-Group 16) semiconductors (e.g., CdTe, CdSe, CdZnTe, ZnSe, ZnTe, CuO, etc.), or any combination thereof. In yet further embodiments, the first and second semiconductor layers 442 and 444 include polyacetylene (PA) or any of its derivatives, polythiophene (PT) or any of its derivatives, poly(p-phenyl vinylene) (PPV) or any of its derivatives such as MEH-PPV, fullerene molecules such as C₆₀ or any of its derivatives, bucky tubes, anthracene, tetracene, pentacene, Alq₃ or other metal-chelate (M-L₃) type organometallic molecules, or any combination thereof. Either or both of the first and second semiconductor layers 442 and 444 can also be a composite comprising organic and inorganic materials or in the form of bi-layer or multiple-layers of such materials.

In one embodiment, the first semiconductor layer 442 includes silicon as the only semiconductor material, and the second semiconductor layer 444 includes germanium, silicon germanium, or another semiconductor material different from silicon alone or mixed with silicon. The significance of the different materials within the first and second semiconductor layers 442 and 444 will become apparent during a patterning sequence as described later in this specification.

The first semiconductor layer 442 is undoped or has n-type or p-type dopant at a concentration no greater than approximately 1×1 0¹⁹ atoms/cm³. The second semiconductor layer 444 includes an n-type or p-type dopant at a concentration heavier than the first semiconductor layer 442. In one embodiment, the second semiconductor layer 444 is n⁺ or p⁺ doped to at least 1×10¹⁹ atoms/cm³ in order to form ohmic contacts with subsequently-formed metal-containing structures. In another embodiment, the dopant concentration within the second semiconductor layer 444 is less than 1×10¹⁹ atoms/cm³ and forms Schottky contacts when contacted with subsequently-formed metal-containing structures. Conventional n-type dopants (phosphorous, arsenic, antimony, etc.) or p-type dopant (boron, gallium, aluminum, etc.) can be used. Such dopants can be incorporated during deposition or added during a separate doping sequence (e.g., implanting and annealing). The first and second semiconductor layers 442 and 444 are formed using conventional deposition and doping techniques. In one embodiment, the thickness of the first semiconductor layer 442 is in a range of approximately 30 to 550 nm, and the thickness of the second semiconductor layer 444 is in a range of approximately 50 to 500 nm. After reading this specification, skilled artisans will appreciate that other thicknesses may be used to achieve the desired electronic characteristics of the driving transistor 126.

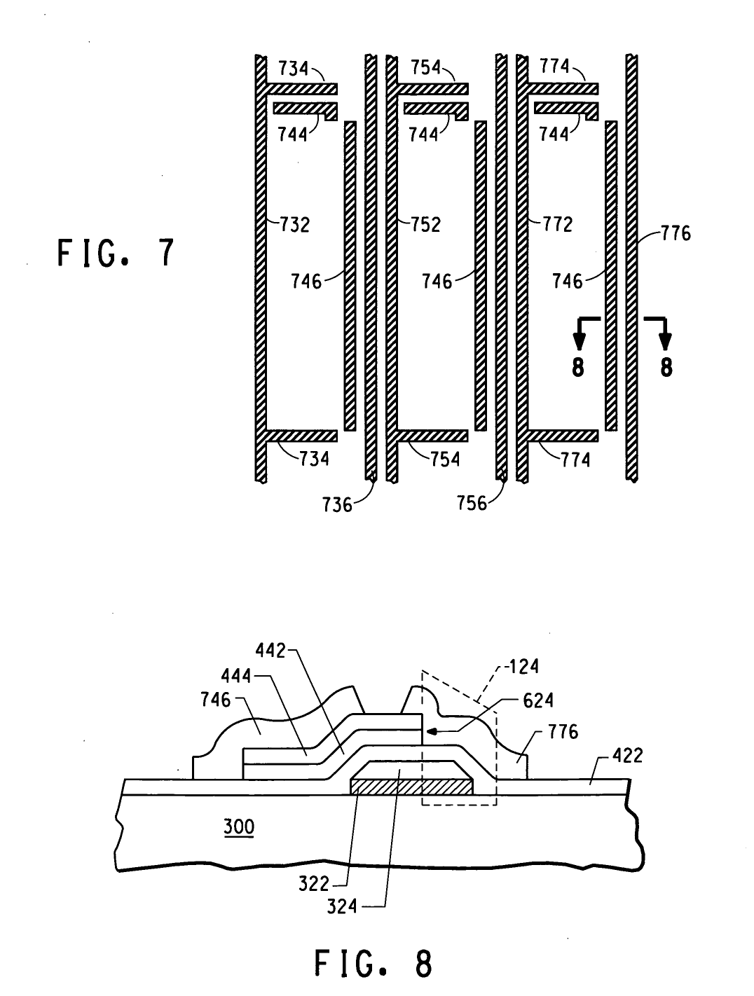

The first and second semiconductor layers 442 and 444 are patterned to form active regions 522 and 526 for the select transistors 122 and driving transistors 126, respectively, as illustrated in FIG. 5. The active regions 522 and 526 will be subsequently patterned to define channel and source/drain regions for the select and driving transistors 122 and 126.

The first and second semiconductor layers 442 and 444 are patterned using a conventional lithographic technique. The structure formed in FIG. 6 has a pair of edges 622 and 624. Note that the first and second semiconductor layers 442 and 444 are coterminous at each of the edges 622 and 624. In another embodiment, the first and second semiconductor layers 442 and 444 are deposited as patterned layers using a stencil mask to form the patterned first and second semiconductor layers 442 and 444 as illustrated in FIG. 6. Note that a portion of the conductive layer 324 extends to the right of the edge 624 in FIG. 6. That portion of the conductive layer 324 is a first electrode for the capacitive electronic component 124. The portion of the dielectric layer 422 to the right of the edge 624 and contacting the conductive layer 324 is the capacitor dielectric layer for the capacitive electronic component 124. The portion of the dielectric layer 422 to the left of the edge 624 and contacting the conductive layer 324 is the gate dielectric layer for the driving transistor 126.

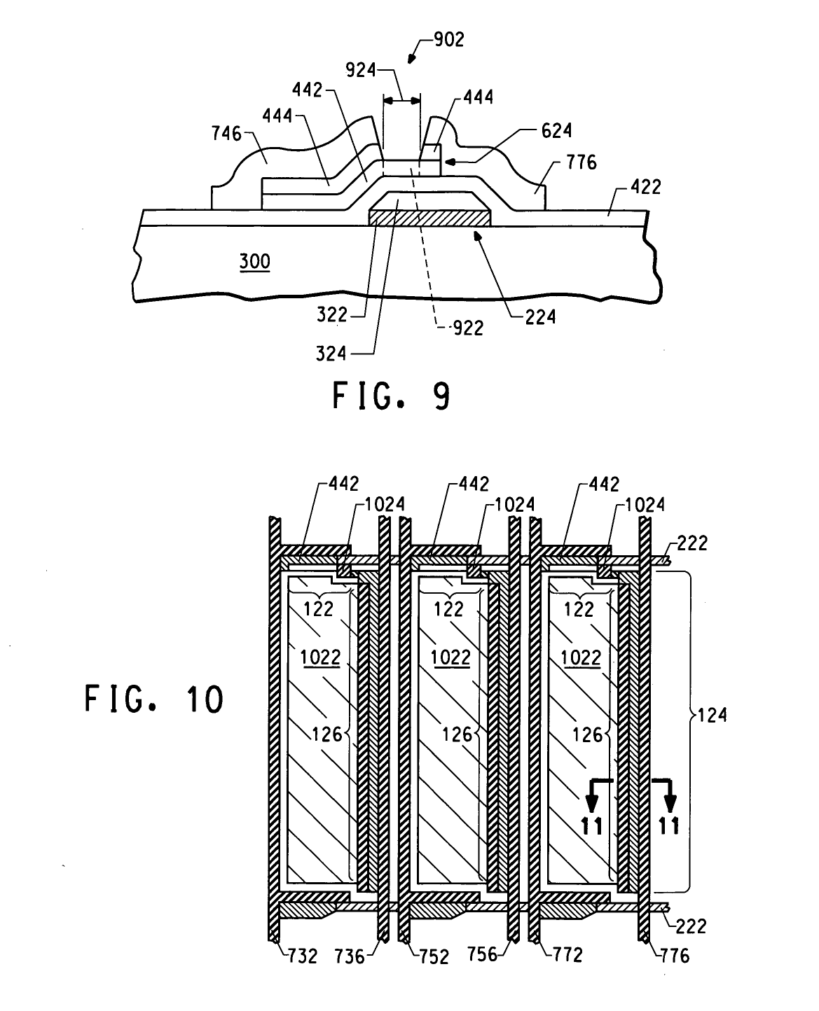

Conductive members 732, 736, 744, 746, 752, 756, 772, and 776 are formed over the substrate 300 as illustrated in FIG. 7. Underlying layers are not illustrated in FIG. 7 to simplify understanding of the positional relationships between the conductive members 732, 736, 744, 746, 752, 756, 772, and 776. The conductive member 732 is part of the data line 132 and includes portions 734. The portion 734 of the conductive member 732 that is closer to the top of FIG. 7 is the first source/drain contact structure for the select transistor 122 within pixel 120. The other portion 734 is the first source/drain contact structure for the select transistor 122 within the pixel (not illustrated) below pixel 120. The conductive member 752 is part of the data line 152 and includes portions 754. The portion 754 of the conductive member 752 that is the closer to the top of FIG. 7 is the first source/drain contact structure for the select transistor 122 within pixel 140. The other portion 754 is the first source/drain contact structure for the select transistor 122 within the pixel (not illustrated) below pixel 140. The conductive member 772 is part of the data line 172 and includes portions 774. The portion 774 of the conductive member 772 closer to the top of FIG. 7 is the first source/drain contact structure for the select transistor 122 within pixel 160. The other portion 774 is the first source/drain contact structure for the select transistor 122 within the pixel (not illustrated) below pixel 160.

The conductive members 744 are the second source/drain contact structures for the select transistors 122. The conductive members 746 are the first source/drain contact structures for the driving transistors 126. The conductive member 736 is part of the V_{dd1} line 136, the conductive member 756 is part of the V_{dd2} line 156, and the conductive member 776 is part of the V_{dd3} line 176.

Referring to FIG. 8, the portion of the conductive member 776 lying to the right of edge 624 is the second electrode for the capacitive electronic component 124 within pixel 160. The portion of the conductive member 776 lying to the left of edge 624 is part of the contact structure for the second source/drain region of the driving transistor 126 within pixel 160. The capacitive electronic component 124, illustrated with a dashed line in FIG. 8, within pixel 160 includes the portions of the conductive layer 324, the dielectric layer 422, and conductive member 776 that lie to the right of the edge 624. The capacitive electronic components 124 for the pixels 120 and 140 have similar structures. Portions of the conductive members 736 and 756 are second electrodes for the capacitive electronic components of the pixels 120 and 140, respectively.

Conductive members 732, 736, 744, 746, 752, 756, 772, and 776 can be formed using a conventional technique. In one embodiment, a stencil mask may be used during a deposition operation to form the conductive members 732, 736, 744, 746, 752, 756, 772, and 776. In another embodiment, the conductive members 732, 736, 744, 746, 752, 756, 772, and 776 are formed by depositing one or more layers over substantially all of the substrate 300 and using a conventional lithographic technique to pattern the layer(s). Any of the materials and thicknesses described with respect to the conductive layer 324 may be used for the conductive members 732, 736, 744, 746, 752, 756, 772, and 776. In one embodiment, the conductive members 732, 736, 744, 746, 752, 756, 772, and 776 have the substantially same composition and thickness as the conductive layer 324. In another embodiment, the conductive members 732, 736, 744, 746, 752, 756, 772, and 776 have a different composition, thickness, or both compared to conductive layer 324.

Referring to FIG. 7, from a plan view of the electronic device, exposed portions (not illustrated in FIG. 7) of the second semiconductor layer 444 lies between each of: (1) conductive member 744 and the portion 734 of the conductive member 732; (2) conductive member 744 and the portion 754 of the conductive member 752; (3) conductive member 744 and the portion 774 of the conductive member 772; (4) conductive member 746 and the conductive member 736; (5) conductive member 746 and the conductive member 756; and (6) conductive member 746 and the conductive member 776.

In one embodiment, each of the spacings between conductive members over the second semiconductor layer 444 is approximately at a minimum dimension for the design rules used. In one embodiment, when 4-micron design rules are used, the spaces are approximately 4 microns each. In another embodiment, the spaces are more than the minimum dimension for the design rules. After reading this specification, skilled artisans will be able to choose a spacing between the drain and source contacts that best meets the needs or desires for a particular transistor design.

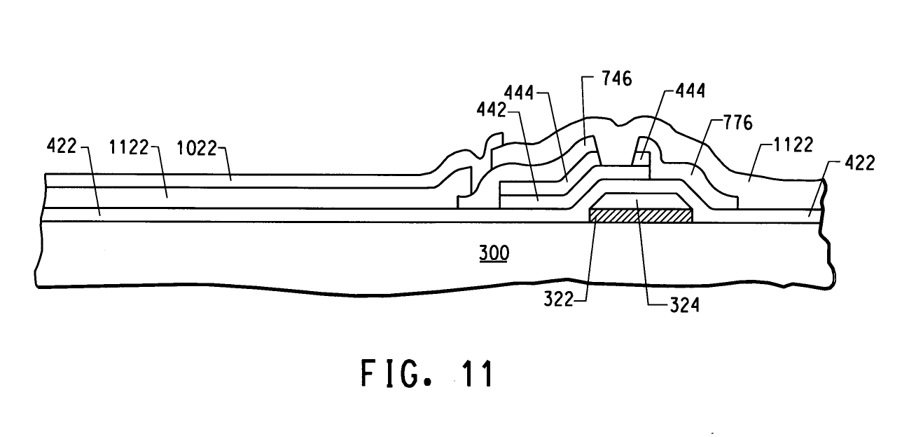

The exposed portion of the second semiconductor layer 444 is then removed to form an opening 902 that extends through the second semiconductor layer 444 as illustrated in FIG. 9. In this embodiment, the conductive members 746 and 776 are part of a hard mask when removing the exposed portion of the second semiconductor layer 444. Remaining portions of the second semiconductor layer 844 are spaced apart from one another and are source/drain regions for the select and driving transistors 122 and 126. Within the third pixel 160, the channel region for the driving transistor 126 is self-aligned to the conductive members 746 and 776. The channel regions 922 for the other driving transistors 126 and select transistors 122 are formed in substantially the same manner at substantially the same time. The select and driving transistors 122 and 126 are under-gated TFTs because the gate electrodes for those transistors underlie their corresponding channel regions 922. The portions of the dielectric layer 422 lying between the conductive members 722 and the overlying channel regions 922 of the select and driving transistors 122 and 126 are the gate dielectric layers for those select and driving transistors 122 and 126.

Each of the physical channel lengths 924 of the channel regions 922 is the distance between portions of the second semiconductor layer 444 along the opening 902. In one embodiment, one or more of the physical channel lengths 924 are no more than two times the minimum dimension of the design rules. In another embodiment, one or more of the physical channel lengths 924 are no more than 1.2 times the minimum dimension of the design rules. In another embodiment, the physical channel length 924 may be larger or smaller than those described.

The etch of the second semiconductor layer 444 may be performed using a wet or dry etch technique. In one embodiment, the etchants can be selected to allow the second semiconductor layer 444 to be removed selectively (i.e., etch at a higher rate) with respect to the conductive members 732, 736, 744, 746, 752, 756, 772, and 776.

In one embodiment, a halogen-containing plasma may be used by performing a dry etching technique to remove the exposed portion of the second semiconductor layer 444. The feed gas can include a halogen-containing gas, such as a fluorine-containing gas. The halogen-containing gas can have a formula of CₐX_{b}H_{c}, wherein X is one or more halogens, a is 1 or 2, b is at least one, and b+c is 4 if a is 1 and b+c is 4 or 6 if a is 2. For example, when X is F, the halogen-containing gas is a fluorocarbon. In another embodiment, the fluorine-containing gas can include F₂, HF, SF₆, NF₃, a fluorine-containing interhalogen (ClF, ClF₃, ClF₅, BrF₃, BrF₅, and IF₅), or any mixture thereof. In another embodiment, the halogen-containing gas is a chlorine-containing gas including Cl₂, HCl, BCl₃, a chlorine-containing interhalogen (ClF, ClF₃, and ClF₅), or any mixture thereof. In still another embodiment, the halogen-containing gas is a bromine-containing gas including Br₂, HBr, BBr₃, a bromine-containing interhalogen (BrF₃ and BrF₅), or any mixture thereof. In yet another embodiment, the halogen-containing gas is an iodine-containing gas including I₂, HI, or any mixture thereof. In still a further embodiment, the halogen-containing gas is any mixture of gases described in this paragraph. In a specific embodiment, the etching selectivity between the second semiconductor layer 444 and the first semiconductor layer 442 (i.e., ratio of the etch rate of the second semiconductor layer 444 to the etch rate of the first semiconductor layer 442) can be improved by using more of the heavier halogens as compared to fluorine. For example, the etching selectivity improves with CF_{(1-y)}Cl_{y} as y increases.

The feed gas can include any one or more oxygen-containing gases, such as of O₂, O₃, N₂O, or other oxygen-containing gas conventionally used for creating an oxygen plasma within the semiconductor arts. The feed gas can also include one or more inert gases (e.g., a noble gas, N₂, CO₂, or any combination thereof).

The etch can be performed within an etch chamber. During the etch, the pressure is in a range of approximately 0.01 to 5000 mTorr. At these pressures, the feed gas(es) may flow at a rate in a range of approximately 10 to 1000 standard cubic centimeters per minute (“sccm”). In another embodiment, the pressure may be in a range of approximately 100 to 500 mTorr, the feed gas(es) may flow at a rate in a range of approximately 100 to 500 sccm. The voltage and power may be applied to generate a plasma. Power is typically a linear or near linear function of the surface area of the substrate. Therefore, power densities (in power per unit area of substrate) are given. The voltage is in a range of approximately 10 to 1000 V, and the power density is in a range of approximately 10 to 5000 mW/cm². In one embodiment, the voltage may be in a range of approximately 20 to 300 V, and the power density may be in a range of approximately 50 to 500 mW/cm².

The etch may be performed as a timed etch or by using endpoint detection with a timed overetch. If the first and second semiconductor layers 442 and 444 are mostly silicon, a timed etch may be used. If dissimilar materials are used for the first and second semiconductor layers 442 and 444, endpoint detection may be used. For example, in one embodiment, if the second semiconductor layer 444 includes silicon germanium, endpoint detection may be based on the absence of germanium in the effluent from the etch chamber after the first semiconductor layer 442 becomes exposed. In another embodiment, if the second semiconductor layer 444 includes germanium with nearly no silicon, endpoint detection may be based on the presence of silicon within the effluent from the etch chamber after the first semiconductor layer 442 is exposed. A timed overetch may be used to ensure that portions of the second semiconductor layer 444 are removed from areas of the substrate 300 where etching occurs more slowly. In one embodiment, the power density during the etch may be decreased during the overetch to improve selectivity of the second semiconductor layer 444 to the first semiconductor layer 442 and other portions of the electronic device exposed to the etching plasma.

Wet chemical etchants selected will be based in part on the composition of the second semiconductor layer 444 and other portions of the electronic device exposed during the etch. In one embodiment, the etchant can include a base (e.g., KOH, tetramethyl ammonium hydroxide, etc.) or a combination of an oxidizer (e.g., HNO₃) and HF. A timed etch is typically used for wet chemical etching.

After the etching is completed, some or none of the first semiconductor layer 442 may be removed. In one embodiment, no more than approximately 50 nm of the first semiconductor layer 442 is removed.

At this point in the process, the formation of the electronic components within the pixel driving circuits is substantially complete. Referring to FIG. 9, within pixel 160, the portion of the conductive layer 324 to the left of the edge 624 includes the gate electrode for the driving transistor 126. The portion of the conductive layer 324 to the right of the edge 624 is the first electrode for the capacitive electronic component 124. The portion of the second semiconductor layer 444 underlying the conductive member 746 is a first source/drain region for the driving transistor 126, and the portion of the second semiconductor layer 444 underlying the conductive member 776 is a second source/drain region for the driving transistor 126. The portion of the first semiconductor layer exposed within the opening 902 is the channel region of the driving transistor 126. The portion of the conductive member 776 to the right of the edge 624 is the second electrode for the capacitive electronic component 124. The other driving transistors 126 and capacitive electronic components 124 within the other pixels 120 and 140 are substantially identical to those illustrated in FIG. 9.

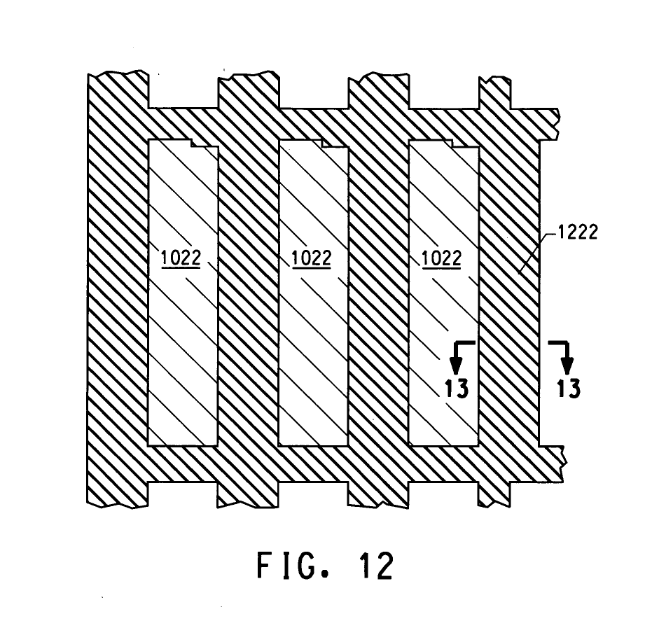

An insulating layer and contact openings within the insulating layer are formed over portions of the substrate 300. Conductive members 1022 and 1024 are formed over portions of the substrate 300 as illustrated in FIG. 10. Conductive members 1022 are first electrodes for the electronic components 128, 148, and 168 and are connected to the underlying conductive members 746. Within each pixel 120, 140, and 160, the conductive member 1024 is connected to the conductive members 744 and the conductive members 224. The conductive members 1024 are local interconnects to connect the second source/drain regions of the select transistors 122 to the gate electrodes of the driving transistors 126 and the first electrodes of the capacitive electronic components 124.

At this point in the process, the pixel driving circuits are formed and include the select transistors 122, the capacitive electronic components 124, and the driving transistors 126. Referring to FIG. 10, the length of the select transistors 122 are substantially parallel to the lengths of the conductive members 222, which are also the select lines 134, and extend side to side as illustrated in FIG. 10. The lengths of the capacitive electronic components 124 and the driving transistors 126 are substantially parallel to the lengths of the conductive members 736, 756, and 776. For each of the select transistors 122, the capacitive electronic components 124, and the driving transistors 126, their lengths are larger than their corresponding widths as seen from a plan view of the electronic device. In one embodiment, the lengths of the capacitive electronic components 124 are longer than the lengths of the driving transistors 126. In another embodiment, the lengths of the capacitive electronic components 124 are shorter than or substantially the same as the lengths of the driving transistors 126.

From a plan view, within each of the pixels 120, 140, and 160, the driving transistor 126 and the capacitive electronic component 124 are substantially contiguous to each other along a line that is substantially parallel to the lengths of the driving transistor 126 and the capacitive electronic component 124. In one embodiment, the line corresponds to the edge 624 as illustrated in FIG. 9. The driving transistor 126 lies to the left of the edge 624, and the capacitive electronic component 124 lies to the right of the edge 624. As used in this specification, contiguous can include physically distinct structures that contact each other or include physically indistinct structures that extend across a line, as illustrated in FIGS. 9 and 10. More specifically, portions of the conductive member 224, the dielectric layer 422, and conductive member 776 to the left of the edge 624 are parts of or contact structures for the driving transistor 126 within pixel 160. Portions of the conductive member 224, the dielectric layer 422, and conductive member 776 to the right of the edge 624 are parts of or contact structures for the capacitive electronic component 124 within pixel 160. Each of the conductive member 224, the dielectric layer 422, and conductive member 776 extends continuously across the edge 624. Therefore, the capacitive electronic component 124 and driving transistor 126 are substantially contiguous within pixel 160. The other pixels 120 and 140 have substantially identical features.

Within each of pixels 120, 140, and 160, the lengths of the select transistor 122 lies along a first side of the pixel, and the length of the driving transistor 126 lies along a second side of the pixel. In one specific embodiment, each of the first sides of the pixels is substantially perpendicular to each of the second sides of the pixels. In another specific embodiment, the lengths of the driving transistors 126 are at least half of the length of the second side of the pixel. In one embodiment, the lengths of the driving transistors extend more than 70% of the length of the second sides of the pixels, and in a more specific embodiment, extend more than 85% of the lengths of the second sides of the pixels.

FIG. 11 includes a cross-sectional view at sectioning line 11-11 in FIG. 10 and illustrates the fabrication of the electronic device after the conductive members 1022 and 1024 are formed. The insulating layer 1122 and openings within the insulating layer 1122 can be formed using one or more conventional techniques. In one embodiment, the insulating layer 1122 is deposited as a patterned layer using a stencil mask. In another embodiment, the insulating layer 1122 can be blanket deposited over substantially all of the substrate 300 and patterned using a conventional lithographic technique. The insulating layer 1122 can include one or more layers of any of the materials previously described with respect to the dielectric layer 422. The thickness of the insulating layer 1122 is in a range of approximately 0.1 to 5.0 microns.

The conductive members 1022 and 1024 can include one or more layers of one or more materials conventionally used for an anode in a conventional OLED. The conductive members 1022 and 1024 can be formed using a conventional deposition or by a conventional deposition and patterning sequence.

In one embodiment, the conductive members 1022 transmits at least 70% of the radiation to be emitted from or responded to by subsequently-formed organic active layer(s). In one embodiment, the thickness of the conductive members 1022 and 1024 is in a range of approximately 100 to 200 nm. If radiation does not need to be transmitted through the conductive members 1022 and 1024, the thickness may be greater, such as up to 1000 nm or even thicker.

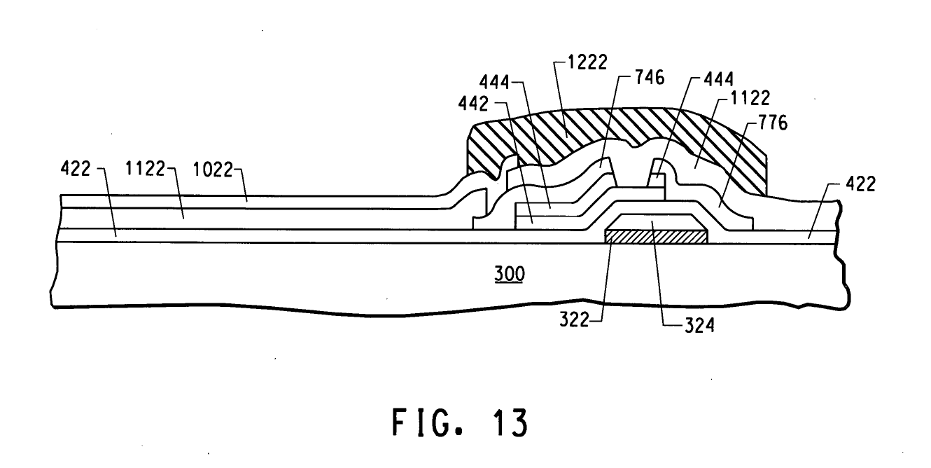

A substrate structure 1222 is formed over the pixel driving circuits as illustrated in FIG. 12. In one embodiment, the substrate structure 1222 is a well structure, and in another embodiment the substrate structure 1222 can be a liquid guide structure (i.e., having shapes in the form of strips rather than a lattice). In one embodiment, at least portions of the substrate structure 1222 lies between the electronic components 128, 148, 168, or any combination thereof and at least portions of the select and driving transistors 122 and 126 (e.g., at least half of the select and driving transistors 122 and 126). In another embodiment, substantially all of the pixel driving circuits, including the select and driving transistors 122 and 126 and capacitive electronic components 124, are covered by the substrate structure 1222. In yet another embodiment, the channel regions of the select and driving transistors 122 and 126 are covered by the substrate structure 1222.

FIG. 13 includes a cross-sectional view at sectioning line 13-13 in FIG. 12 to illustrate the positional relationship between a portion of the substrate structure 1222 and the underlying driving transistor 126 and capacitive electronic component 124 within pixel 160. The substrate structure 1222 overlies a substrate 300 and portions of the conductive members 1022. The substrate structure 1222 defines an array of openings where radiation can be transmitted to or from a subsequently-formed organic active layer. The openings within the substrate structure 1222 expose portions of the conductive members 1022.

In a specific embodiment, the substrate structure 1222 includes an inorganic (e.g., silicon dioxide, silicon nitride, aluminum oxide, aluminum nitride, etc.) or organic material (e.g., photoresist, polyimide, etc.), or any combination thereof. In another embodiment, the substrate structure 122 can include a black layer (e.g., layer including carbon) in order to increase contrast to ambient light while the electronic device is being operated. In one exemplary embodiment, the substrate structure 1222 may be formed from one or more resist or polymeric layers. The resist may, for example, be a negative resist material or positive resist material.

The resist can be deposited over the substrate 300 and conductive members 1022 using a conventional technique. The substrate structure 1222 may be patterned as deposited or may be deposited as a blanket layer and patterned using a conventional lithographic technique. In one particular embodiment, the substrate structure 1222 has a thickness between approximately 2 to 10 microns as viewed from a cross-sectional view. In one exemplary embodiment, openings within the substrate structure 1222 are in a range of approximately 50 to 100 microns wide and in a range of approximately 100 to 500 microns long when viewed from a plan view. The slope of the substrate structure 1222 at the openings may be less than 90°, approximately 90°, or more than 90°with respect to the surface of the conductive members 1022.

In one embodiment, the substrate structure 1222 may or may not receive a surface treatment before forming a subsequent organic layer. A conventional fluorination surface treatment may be performed to reduce the surface energy of the substrate structure 1222.

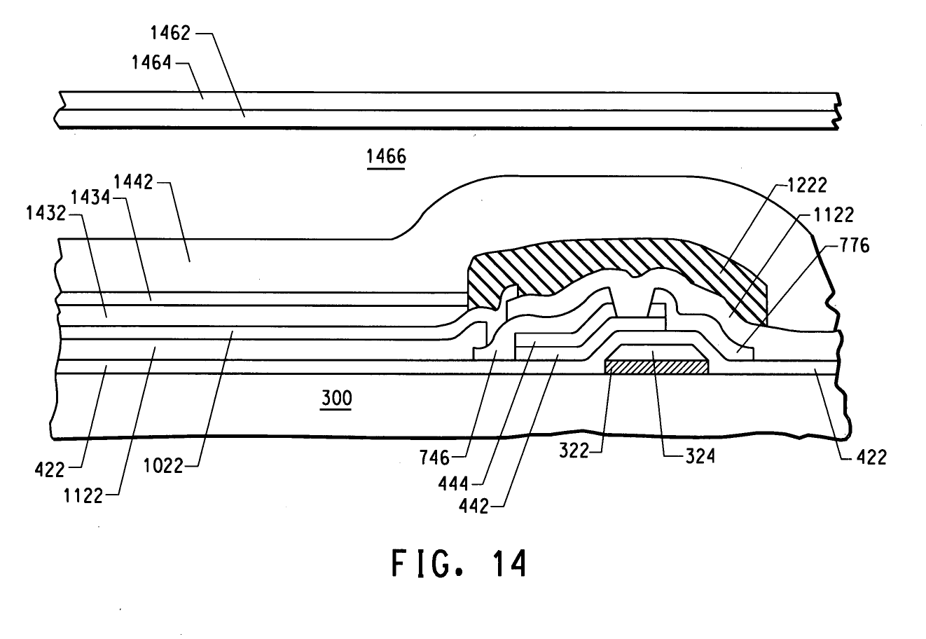

Processing continues to form a substantially completed electronic component as illustrated in FIG. 14. An organic layer 1430 and a second electrode 1442 are formed over the substrate 300. The organic layer 1430 may include one or more layers. The organic layer 1430 includes an organic active layer 1434, and optionally, may contain any one or more of a charge-injection layer, a charge-transport layer, a charge-blocking layer, or any combination thereof. The optional charge-injection layer, charge-transport layer, charge-blocking layer, or any combination thereof may lie a between the organic active layer 1434 and the conductive members 1022, between the organic active layer 1434 and the second electrode 1442, or a combination thereof. In one embodiment, a hole-transport layer 1432 lies between the conductive members 1022 and the organic active layer 1434.

The formation of the organic layer 1430 is performed using any one or more conventional techniques used in forming organic layers in OLEDs. The hole-transport layer 1432 has a thickness in a range of approximately 50 to 200 nm, and the organic active layer 1434 has a thickness in a range of approximately 50 to 100 nm. In one embodiment, only one organic active layer is used in the array. In another embodiment, different organic active layers may be used in different parts of the array.

The second electrode 1442 includes one or more layers of one or more materials used for a cathode in a conventional OLED. The second electrode 1442 is formed using one or more conventional deposition or conventional deposition and lithographic techniques. In one embodiment, the second electrode 1442 has a thickness in a range of approximately 0.1 to 5.0 microns. In a specific embodiment, the second electrode 1442 can be a common cathode for the array.

Other circuitry not illustrated in FIG. 14 may be formed using any number of the previously described or additional layers. Although not shown, additional insulating layer(s) and interconnect level(s) may be formed to allow for circuitry in peripheral areas (not shown) that may lie outside the array. Such circuitry may include row or column decoders, strobes (e.g., row array strobe, column array strobe), or sense amplifiers. Alternatively, such circuitry may be formed before, during, or after the formation of any layers shown in FIG. 14. In one embodiment, the second electrode 1442 is part of the Vₛₛ line 138.

A lid 1462 with a desiccant 1464 is attached to the substrate 300 at locations (not illustrated in FIG. 14) outside the array to form a substantially completed device. A gap 1466 may or may not lie between the second electrode 1442 and the desiccant 1464. The materials used for the lid and desiccant and the attaching process are conventional.

4. Other Embodiments

The embodiments described above are well suited for AMOLED displays including monochromatic and full color displays. Still, the concepts described herein can be used for other types of radiation-emitting electronic components. Other radiation-emitting electronic components can include passive matrix displays light panels, inorganic LEDs, including III-V or II-VI-based inorganic radiation-emitting components. In one embodiment, the radiation-emitting electronic components may emit radiation within the visible light spectrum, and in another embodiment, the radiation-emitting electronic component may emit radiation outside the visible light spectrum (e.g., UV or IR).

In another embodiment, the concepts described herein may be extended to other types of electronic devices. In one embodiment, a sensor array may include an array of radiation-responsive electronic components. In one embodiment, different radiation-responsive electronic components may have the same or different active materials. The response of those active materials may change over time. Further, some of the sensor array may have different portions that receive different wavelengths, different radiation intensities, or a combination thereof. Similar to an electronic device with radiation-emitting electronic components, the lifetime of an electronic device with radiation-responsive electronic components may have a longer useful life.

Radiation may be transmitted through the substrate 300, the lid 1462, or both. If radiation were to be transmitted through the lid 1462, the lid would allow at least 70% of the radiation to be transmitted through it. The desiccant 1464 can be modified to allow at least 70% of the radiation to be transmitted through it or located at position(s), such that radiation can be emitted from or received by the organic active layer 1434 via the lid 1462. For example, the desiccant may overlie the substrate structure 1322 and not the organic active layer 1434. In another embodiment, the compositions of the conductive members 1022 and 1442 can be reversed. In this embodiment, cathodes are closer to the substrate 300 as compared to a common anode. The pixel driving circuit and interconnects between electronic components may be modified for such a structure.

The capacitance of the capacitive electronic components 124 can be increased or decreased the overlap between any one or more of the conductive members 224 and its overlying conductive member 736, 756, or 776. For example, the portions of the conductive members 224, 736, 756, 776, or any combination thereof that are part of the capacitive electronic components 124 may be narrower, wider, longer, or short compared to what is illustrated in FIGS. 9 and 10. Note that changes to the capacitance of the capacitive electronic components 124 may or may not be made independently from the driving transistors 126 (e.g., portions of the conductive members 224, 736, 756, 776 or any combination thereof that are within or contact structures to the driving transistors 126).

Similarly, the electronic characteristics of the driving transistors 126 can be changed by changing the lengths of the active regions 526 (e.g., lengths of the active regions 526). Note that changes to the electronic characteristics of the driving transistors 126 may or may not be made independently from the capacitive electronic components 124 (e.g., portions of the conductive members 224, 736, 756, 776 or any combination thereof that part of the capacitive electronic components 124).

Many dimensions, including thicknesses, widths, and lengths, have been given with respect to some embodiments. The scope of the present invention is not limited to those dimensions or ranges of dimensions. After reading the specification, skilled artisans will appreciate that other dimensions can be used.

5. Advantages

The layout and electronic component structures described herein can allow a more efficient use of space within a pixel to increase the aperture ratio of the pixel compared to conventional pixels. In one embodiment, within each pixel, the capacitive electronic component 124 and the driving transistor 126 are substantially contiguous with each other. Such an arrangement allows the pixel driving circuits to occupy less area within the pixel because a minimum dimension separation does not need to be maintained between the capacitive electronic component 124 and the driving transistor 126. Also, the lengths of the select and driving transistors 122 and 126 lie along different sides of the pixel.

An aperture ratio of at least 40% can be achieved. In one embodiment, the aperture ratio is at least 50%, in one specific embodiment, the aperture ratio is approximately 53%, and in an even more specific embodiment, the aperture ratio is approximately 55%. Such aperture ratios have not been achieved in conventional bottom emission organic electronic devices. The larger aperture ratio can allow the pixel circuits, including the driving transistors 126 and electronic components 128, 148, and 168 to be operated at less aggressive conditions (i.e., lower current) and still achieve a desired intensity. By reducing the current, the lifetime of the electronic device is extended because the driving transistors 126 and the electronic components 128, 148, and 168 are not degraded as quickly.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense and all such modifications are intended to be included within the scope of the invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

It is to be appreciated that certain features of the invention which are, for clarity, described above and below in the context of separate embodiments, may also be provided in combination in a single embodiment. Conversely, various features of the invention that are, for brevity, described in the context of a single embodiment, may also be provided separately or in any subcombination. Further, reference to values stated in ranges includes each and every value within that range.

What is claimed is:

1. An organic electronic device comprising a pixel, wherein the pixel comprises:
a first transistor, wherein:
the first transistor is an under-gated TFT; and
a first portion of a first conductive member is a gate electrode of the first transistor; and
a capacitive electronic component, wherein a second portion of the first conductive member is a first electrode of the capacitive electronic component.

2. The organic electronic device of claim 1, wherein:
a first portion of a second conductive member is a contact structure for a source/drain region of the first transistor; and
a second portion of the second conductive member is a second electrode of the capacitive electronic component.

3. The organic electronic device of claim 2, wherein:
a first portion of a first layer is at least part of a gate dielectric layer for the first transistor; and
a second portion of the first layer is at least part of a capacitor dielectric layer for the capacitive electronic component.

4. The organic electronic device of claim 2, wherein:
the first transistor comprises:
a channel region that comprises a portion of a first semiconductor layer; and
source/drain regions that are spaced-apart portions of a second semiconductor layer overlying the first semiconductor layer; and
the second semiconductor layer contacts and overlies the channel region and source/drain regions of the first transistor.

5. The organic electronic device of claim 4, wherein, from a cross-sectional view, at least a portion of the source/drain regions lies between the first and second conductive members.

6. The organic electronic device of claim 5, wherein the pixel further comprises a select transistor that is an under-gated TFT.

7. The organic electronic device of claim 3, wherein the first semiconductor layer was formed as amorphous silicon (a-Si), low-temperature polysilicon (LTPS), continuous grain silicon (CGS), or any combination thereof.

8. The organic electronic device of claim 1, wherein:
the organic electronic device is a bottom emission electronic device; and
the pixel has an aperture ratio of at least 40%.

9. The organic electronic device of claim 1, further comprising a select transistor wherein:
the select transistor comprises a channel region;
the channel region of the select transistor, the first transistor, or both has a physical channel length; and
the physical channel length is no more than 2 times greater than a minimum dimension of design rules for the organic electronic device.

10. The organic electronic device of claim 9, wherein the physical channel length is no more than 1.2 times greater than the minimum dimension of the design rules for the organic electronic device.

11. An organic electronic device comprising a pixel, wherein the pixel comprises:
a first transistor, which from a plan view has a length and a width, wherein the length of the first transistor is larger than the width of the first transistor; and
a capacitive electronic component, which from a plan view has a length and a width, wherein the length of the capacitive electronic component is larger than the width of the capacitive electronic component,
wherein, from a plan view, the first transistor and the capacitive electronic component are substantially contiguous to each other along a line that is substantially parallel to the lengths of the first transistor and the capacitive electronic component.

12. The organic electronic device of claim 11, wherein the pixel comprises a single conductive member that is a gate electrode for the first transistor and a first electrode for the capacitive electronic component.

13. The organic electronic device of claim 12, wherein:
the pixel comprises a first conductive member and a second conductive member;
a first portion of the first conductive member is a first source/drain region of the first transistor; and
a first portion of the second conductive member is a second electrode of the capacitive electronic component.

14. The organic electronic device of claim 13, wherein:
the pixel comprises a dielectric layer;
a first portion of a dielectric layer is at least part of a gate dielectric layer for the first transistor; and
a second portion of the dielectric layer is at least part of a capacitor dielectric layer for the capacitive electronic component.

15. The organic electronic device of claim 13, wherein:
the first transistor comprises:
a channel region that comprises a portion of a first semiconductor layer; and
the first source/drain region and a second source/drain region are spaced-apart portions of a second semiconductor layer overlying the first semiconductor layer; and
the second semiconductor layer contacts and overlies the first semiconductor layer.

16. The organic electronic device of claim 15, wherein the first semiconductor layer was formed as amorphous silicon (a-Si), low-temperature polysilicon (LTPS), continuous grain silicon (CGS), or any combination thereof.

17. The organic electronic device of claim 15, wherein the pixel further comprises a select transistor that is an under-gated TFT.

18. The organic electronic device of claim 17, wherein:
the select transistor, the first transistor, or both comprise a channel region;
the channel region of the select transistor, the first transistor, or both has a physical channel length; and
the physical channel length is no more than 2 times greater than a minimum dimension of design rules for the organic electronic device.

19. The organic electronic device of claim 18, wherein the physical channel length is no more than 1.2 times greater than the minimum dimension of the design rules for the organic electronic device.

20. The organic electronic device of claim 14, wherein:
the organic electronic device is a bottom emission electronic device; and
the pixel has an aperture ratio of at least 40%.
